(19) United States
(12) Patent Application Publication
(10) Pub. No.: US 2011/0233907 A1
(43) Pub. Date: Sep. 29, 2011

(54) HOUSING FOR AN ELECTRICAL CIRCUIT

(76) Inventors: Michael Struchholz, Reutlingen (DE); Tristan Jobert, Reutlingen (DE); Klaus Offterdinger, Stuttgart (DE); Thomas Klaus, Tuebingen (DE); Dirk Dittmann, Eggenstein (DE)

(21) Appl. No.: 13/120,294

(22) PCT Filed: Jul. 29, 2009
(86) PCT No.: PCT/EP09/59778

§ 371 Date: May 26, 2011

(30) Foreign Application Priority Data
Sep. 24, 2008 (DE) 10 2008 042 335.1

(51) Int. Cl. B60R 21/16; H05K 5/00

(52) U.S. Cl. 280/735; 361/752

(57) ABSTRACT

A housing for an electrical circuit, in particular for a sensor, pins projecting from the housing for the electrical contacting of the circuit, additional pins being provided which are not connected electrically to the circuit but instead are used as mechanical arrangement for fastening the housing to a printed circuit board in particular. The present invention further relates to a housing having an electrical circuit, in particular a sensor, pins projecting from the housing for the electrical contacting of the circuit, at least two pins being connected to one another mechanically via a connecting piece.

### FIELD OF THE INVENTION

The present invention relates to a housing for an electrical circuit.

### BACKGROUND INFORMATION

Housings for electrical circuits, in particular sensors or integrated circuits which are fastened to printed circuit boards, are generally available. The conventional housing is generally formed from plastic, and electrically conductive pins, which are provided for fastening on the circuit board and for the electrical contacting of the electrical circuit situated in the housing, are guided out of the housing. The housings have a row of pins on two diametrically opposed sides.

In particular when situated in a motor vehicle, the housings are exposed to vibrations, in particular interference accelerations. When a sensor is used, in particular an inertial sensor, it is possible for interference accelerations to adversely influence the sensor's sensitivity in the range of the natural frequency.

### SUMMARY

An object of the present invention is to reduce the influence of vibrations, in particular interference accelerations, on electrical circuits, in particular sensors.

One advantage of the example housing according to the present invention is that the sensitivity to interference accelerations is reduced.

In an exemplary embodiment, this is achieved in that an additional pin is provided which is not electrically connected to the circuit of the housing, but is instead provided as mechanical fastening means for the housing, in particular for fastening on a printed circuit board. The additional pin reduces the sensitivity to vibrational excitation. In particular the natural frequency of the housing is shifted to higher frequencies.

In another specific embodiment, a connecting piece is provided between two pins of the housing. The connecting piece also reduces the sensitivity to vibrational excitations. The connecting piece increases the stiffness between the two pins. Accordingly, the mechanical fastening of the housing is stiffer overall, so that the natural frequency is shifted to a higher frequency in this case as well.

In another specific embodiment, the additional pins, which are not electrically connected to the circuit, are situated on one side of the housing.

In another specific embodiment, the electrical circuit is designed as a sensor, in particular as an inertial sensor for an airbag or ESP system. In the case of inertial sensors in particular, it is advantageous to reduce the influence of interference accelerations.

In another specific embodiment, all pins of one side are connected to one another via at least one connecting piece. A high level of pin stiffness is achieved in this way.

In another specific embodiment, groups of pins connected to one another are provided, a first group having two pins and a second group having three pins. As a function of the specific embodiment used, this system may result in an advantageous reduction in sensitivity to interference.

In another specific embodiment, groups of additional pins are connected to one another mechanically on one side of the housing via a connecting piece, a first group having two pins and a second group having three pins. In this specific embodiment as well, it is possible to achieve an advantageous reduction of sensitivity to interference.

In another specific embodiment, the connecting piece is at least partially situated in the housing. This makes it possible to achieve reliable and simple fastening of the connecting piece.

In another specific embodiment, the connecting piece is integrally formed with the connected pins or with the connected additional pins. This makes it possible for the connecting piece to be manufactured simply.

Moreover, the connecting piece may be formed from an electrically insulating material in another specific embodiment, also making it possible to connect pins to the connecting piece which are electrically connected to the circuit without a short circuit occurring between the pins. This makes it possible to reduce the influence of interference accelerations without the need for additional pins which are not required for an electrical contacting.

### BRIEF DESCRIPTION OF THE DRAWINGS

FIG. 1 shows a first exemplary embodiment of a housing.

FIG. 2 shows a side view of the housing.

FIG. 3 shows a second specific embodiment of a housing.

FIG. 4 shows a third specific embodiment of a housing.

FIG. 5 shows a fourth specific embodiment of a housing.

### DETAILED DESCRIPTION OF EXAMPLE EMBODIMENTS

FIG. 1 shows a schematic representation of a printed circuit board 12, on which electrical leads 13 and electrical components and/or electrical circuits (not shown) are situated. A housing 1 having an electrical circuit 10 is situated on printed circuit board 12. Housing 1 may be formed from a plastic which completely surrounds electrical circuit 10. Electrical circuit 10 may be designed in the form of a sensor, in particular an inertial sensor. Inertial sensors are used, for example, as part of an airbag system or ESP system in motor vehicles in order to ascertain measured quantities for an acceleration and a yaw rate. Inertial sensors may be designed either as an integral component of control units or as independent sensors. The electrical circuit made up of a control circuit in housing 1 may thus be designed in the form of a control unit and in addition a sensor, for example, in the form of an inertial sensor. Inertial sensors may be designed, for example, in the form of yaw rate sensors which detect Coriolis acceleration as a measuring effect. To that end, the sensor has a mass which is positioned to be capable of oscillating with the aid of spring elements. The spring elements are not shown in FIG. 1.

Furthermore, the housing has electrical terminals in the form of pins 2 which are connected to electrical leads 13 of printed circuit board 12. To that end, the pins are, for example, cemented or soldered to printed circuit board 12. Moreover, at least one part of the pins is connected in an electrically conductive manner to electrical circuit 10 via additional electrical leads 11. Pins 2 may be used to exchange electrical signals between printed circuit board 12 and electrical circuit 10. Moreover, the pins are used for the mechanical fastening of housing 1.

Furthermore, housing 1 has additional pins 3 which project from housing 1 and are connected mechanically to printed circuit board 12. The connection between additional pins 3 is made with the aid of connecting arrangement 30. Connecting arrangement 30 may, for example, be designed in the form of a plug connection, cemented joint or soldered joint. Additional pins 3 are connected mechanically to printed circuit board 12 but are not connected to additional leads 11 and/or not to electrical leads 13 and are thus not connected to electrical circuit 10. The additional pins are only used for the mechanical fastening of housing 1 on printed circuit board 12.

In the represented exemplary embodiment, the pins are situated on diametrically opposed longitudinal sides of housing 1, seven pins being provided in each case. Additional pins 3 are situated diametrically opposed on the shorter transverse sides of housing 1. In the represented exemplary embodiment, two additional pins 3 are in each case situated on one side of the housing. As a function of the selected specific embodiment, more or fewer additional pins 3 may also be provided on one side. Moreover, it is also possible to form additional pins 3 on only one side of the housing.

Due to the positioning of additional pins 3, the sensitivity of the housing or of electrical circuit 10 to interference accelerations is reduced. In particular, the additional pins prevent the natural frequency from exciting vibrations of the housing. For example, the natural frequency is shifted to higher frequencies. This reduces the effect of interference accelerations on the electrical circuit, in particular on sensors.

Pins 2 and additional pins 3 are manufactured, for example, from metal strips and cast into housing 1. In doing so, it is possible to use so-called lead frame technology, for example.

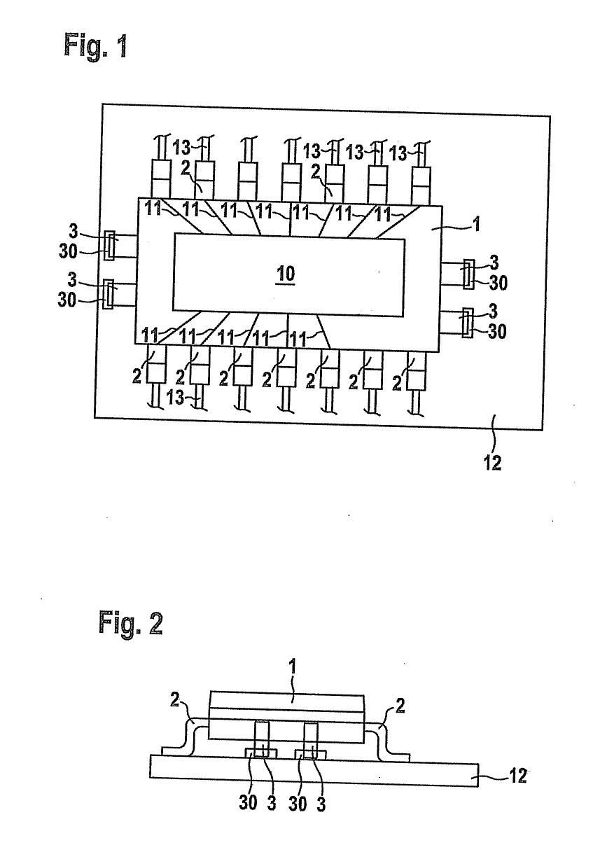

FIG. 2 shows a side view of housing 1 having pins 2 and additional pins 3.

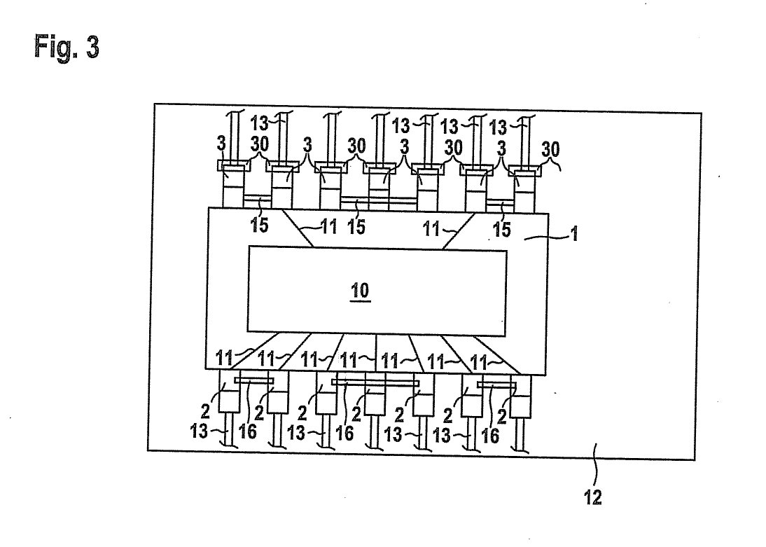

FIG. 3 shows another specific embodiment of a housing 1 having an electrical circuit 10. In this specific embodiment, pins 2, which make an electrical connection possible with electrical circuit 10, are situated on a longitudinal side of housing 1. Additional pins 3 are situated on the diametrically opposed side. Furthermore, groups of additional pins are connected to one another via connecting pieces 15. In the exemplary embodiment shown, two groups of two additional pins 3 and one group of three additional pins 3, which are connected to one another via a connecting piece 15, are situated. This further increases the stiffness of additional pins 3. As a function of the selected specific embodiment, all additional pins 3 of one side of housing 1 may also be connected to one another via a connecting piece 15. Connecting piece 15 may, for example, be integrally formed with the additional pins and may also be formed from a sheet metal piece. As a function of the selected specific embodiment, the connecting piece may also be formed from an electrically non-conductive material.

Another connecting piece 16, which is manufactured from electrically non-conductive material, may also connect groups of pins 2 to one another mechanically without producing an electrically conductive connection between individual pins 2. In the specific embodiment of FIG. 3, two groups of two pins 2 and one group of three pins 2 are connected to one another via an electrically non-conductive connecting piece 16. This embodiment also increases the stiffness of pins 2 and accordingly reduces the sensitivity to interference acceleration. As a function of the selected specific embodiment, other combinations of numbers of pins 2 may also be used for forming groups. In particular, all pins 2 of one side may be connected to one another via an electrically non-conductive additional connecting piece 16. The natural frequency is thus shifted to higher frequencies with the aid of the additional connecting pieces and the sensitivity is reduced accordingly.

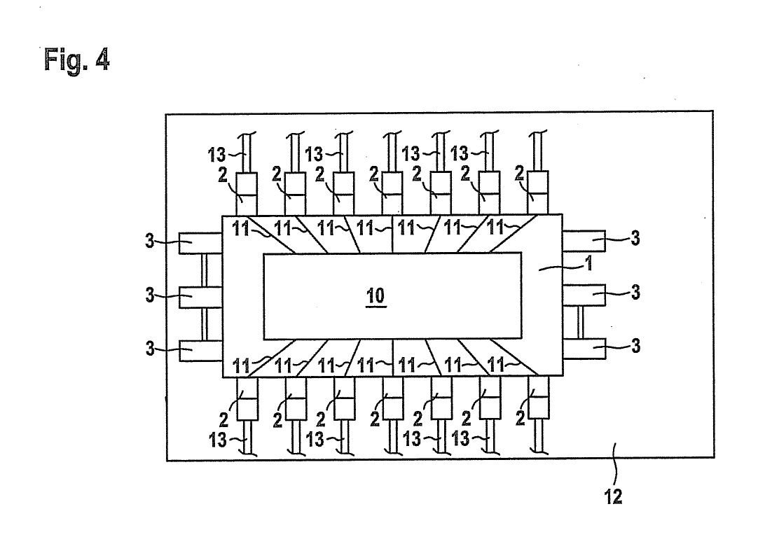

FIG. 4 shows another specific embodiment of a housing 1. In this specific embodiment, three additional pins 3 are situated on each narrow side of housing 1. In this specific embodiment, two additional pins 3 are connected to one another on one side via a connecting piece 15. On the diametrically opposed side, three additional pins 6 are connected to one another via one or two connecting pieces 15. The sensitivity to interference accelerations is reduced in this specific embodiment as well.

As a function of the selected specific embodiment, connecting pieces 15 or additional connecting pieces 16 may also be partially embedded in housing 1. As a result, simple securing of connecting pieces 15 and additional connecting pieces 16 is possible.

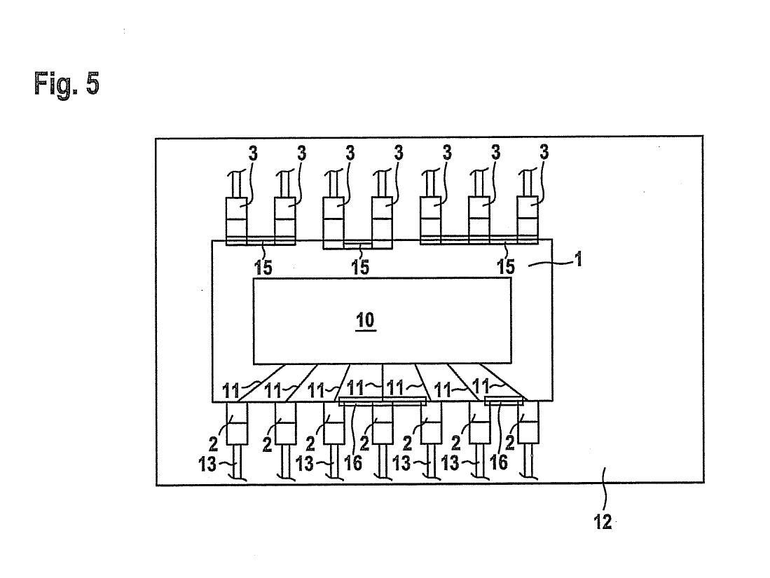

FIG. 5 shows a corresponding specific embodiment in which additional pins 3 are connected to one another in groups of two and three additional pins via a connecting piece 15, connecting piece 15 being at least partially situated in housing 1. Instead of connecting pieces 15, additional connecting pieces 16, which connect the groups of additional pins, may also be provided.

Moreover, additional connecting pieces 16 are formed from electrically non-conductive material, for example, plastic, the additional connecting pieces being partially situated in housing 1, and the groups of pins 2 are mechanically connected to one another.

As a function of the selected specific embodiment, connecting pieces 15 may connect all additional pins of one side to one another mechanically, or additional connecting pieces 16 may connect all pins of one side of housing 1 to one another mechanically.

As a function of the selected specific embodiment, connecting pieces 15 may also be formed from electrically non-conductive material, in particular from plastic.

1-12. (canceled)

13. A housing for an electrical circuit for a sensor, the housing including pins projecting therefrom for electrical contacting of the circuit, and additional pins for a mechanical fastening of the housing to a printed circuit board without electrically contacting the circuit.

14. The housing as recited in claim 13, wherein the pins for the electrical contacting of the circuit includes at least two pins connected to one another mechanically via a connecting piece.

15. The housing as recited in claim 13, wherein the housing has four sides, and the additional pins are situated on one of the sides of the housing.

16. The housing as recited in claim 14, wherein the housing has four sides, the pins for the electrical contacting of the circuit are situated on at least one side of the housing, and the additional pins project from the housing on a second side of the housing.

17. The housing as recited in claim 13, wherein the circuit is an inertial sensor for one of an airbag system or an ESP system.

18. The housing as recited in claim 13, wherein at least two of the additional pins are connected to one another via a connecting piece.

19. The housing as recited in claim 16, wherein all pins of one side of the housing are connected to one another using at least one additional connecting piece.

20. The housing as recited in claim 14, wherein groups of the pins for the electrical contacting of the circuit are connected to one another mechanically via one additional connecting piece, a first group having two pins and a second group having three pins.

21. The housing as recited in claim 13, wherein groups of the additional pins are connected to one another mechanically on one side of the housing via at least one connecting piece, a first group having two additional pins and a second group having three additional pins.

22. The housing as recited in claim 14, wherein the connecting piece is at least partially situated in the housing.

23. The housing as recited in claim 22, wherein the connecting piece is integrally formed with the connected pins.

24. The housing as recited in claim 14, wherein the connecting piece is formed from an electrically insulating material.
